(19) United States
(12) Patent Application Publication
(10) Pub. No.: US 2017/0293037 A1
(43) Pub. Date: Oct. 12, 2017

(54) APPARATUS AND METHOD FOR DETECTION OF X-RAY RADIATION

(71) Applicant: Siemens Healthcare GmbH, Erlangen (DE)

(72) Inventors: Oliver SCHMIDT, Erlangen (DE); Patric BUECHELE, Langenau (DE); Rene FISCHER, Erlangen (DE); Sandro Francesco TEDDE, Weisendorf (DE)

(73) Assignee: Siemens Healthcare GmbH, Erlangen (DE)

(21) Appl. No.: 15/479,846

(22) Filed: Apr. 5, 2017

(30) Foreign Application Priority Data
Apr. 7, 2016 (DE) 102016205818.5

(51) Int. Cl. G01T 1/20; G01T 1/24; H01L 51/44; H01L 51/42; H01L 27/30

(52) U.S. Cl. CPC G01T 1/2018; H01L 51/424; H01L 27/308; H01L 51/441; G01T 1/24

(57) ABSTRACT

A detection apparatus is provided for detection of x-ray radiation, with a lower layer arranged between a lower electrode and a middle electrode. In an embodiment, the lower layer includes at least one first perovskite. In an embodiment, a first voltage is able to be applied between the lower electrode and the middle electrode; and an upper layer is arranged between an upper electrode and the middle electrode. The upper layer features at least one second perovskite and a second voltage is able to be applied between the upper electrode and the middle electrode. Finally, an evaluation device, which is coupled to the upper layer and the lower layer, is embodied to detect an interaction of x-ray radiation with the first perovskite and an interaction of x-ray radiation with the second perovskite.

### PRIORITY STATEMENT

The present application hereby claims priority under 35 U.S.C. §119 to German patent application number DE 102016205818.5 filed Apr. 7, 2016, the entire contents of which are hereby incorporated herein by reference.

### FIELD

At least one embodiment of the present invention generally relates to a detection apparatus for detection of x-ray radiation, to a manufacturing method for a detection apparatus for detection of x-ray radiation and/or to a method for detection of x-ray radiation.

### BACKGROUND

Uses for x-ray detectors are to be found in a diversity of areas. For example x-ray radiation will be employed in industrial production for testing of materials via Non-Destructive Testing (NDT), wherein x-ray radiation with energies of a few megaelectron volts (MeV) is used.

X-ray detectors also play an important role in medical diagnostics, wherein the energies of the x-ray radiation used typically lie in a range of around 20 to 120 kiloelectron volts (keV). The substances being examined exhibit different x-ray absorption spectra. Thus for example the absorption capability of bones, soft parts or tissue differs greatly from one another in different energy ranges. In order not to subject the patient to any disproportionate and unnecessary radiation load the dose of the x-ray radiation will typically be chosen such that the x-ray image only detects structures of a specific category, such as bones or soft parts. The energy of the x-ray radiation used will thus be selected in that range that will be especially strongly absorbed by the structure to be examined.

In many cases it is also necessary however to obtain information about the overall composition of the object to be irradiated. In order now for example to detect both bones and also tissue, x-ray radiation in different energy ranges can be used. In what is referred to as Dual Energy X-ray Absorptiometry, (DEXA) two different recordings will be made with different x-ray energies. To do this it is usual to stack a number of detectors. Such an arrangement of a number of detectors, each with different energy ranges, is known for example from U.S. Pat. No. 8,488,736 B2. By combination of the images the x-ray image can be prevented from having overexposed or underexposed parts.

The stacking of detectors means that it is possible, with a single x-ray source, which emits x-ray radiation in different energy ranges, to create images on the basis of the radiation let through in the respective energy ranges. To do this however a plurality of autonomous detectors will be needed in each case. A demand therefore exists for detection apparatuses with a compact structure.

### SUMMARY

Embodiments of the present invention involve a detection apparatus for detection of x-ray radiation; a manufacturing method for a detection apparatus for detection of x-ray radiation; and a method for detection of x-ray radiation via a detection apparatus.

In accordance with a first embodiment, the present invention accordingly comprises a detection apparatus for detection of x-ray radiation. The detection apparatus comprises a lower layer arranged between a lower electrode and a middle electrode, wherein the lower layer features at least one first perovskite and wherein a first electrical voltage is able to be applied between the lower electrode and the middle electrode. The detection apparatus further comprises an upper layer arranged between an upper electrode and the middle electrode, wherein the upper layer features at least one second perovskite and wherein a second electrical voltage is able to be applied between the upper electrode and the middle electrode. The detection apparatus further comprises an evaluation device, which is coupled to the upper layer and the lower layer and which is embodied to detect an interaction of x-ray radiation with the first perovskite and an interaction of x-ray radiation with the second perovskite.

A further embodiment of the invention accordingly comprises a manufacturing method for a detection apparatus for detection of x-ray radiation, wherein a lower layer, which features at least one first perovskite, will be arranged on a substrate. A middle electrode will further be arranged between the lower layer and an upper layer, wherein the upper layer features at least one second perovskite. An upper electrode will be arranged on a side of the upper layer facing away from the middle electrode. A lower electrode will further be arranged on a side of the lower layer facing away from the middle electrode.

In accordance with a further embodiment, the present invention comprises a method for detection of x-ray radiation via a detection apparatus. Here the evaluation device of the detection apparatus detects x-ray radiation on the basis of an interaction of the x-ray radiation with the first perovskite and/or the second perovskite.

Further preferred forms of embodiment of the present invention are described hereafter.

### BRIEF DESCRIPTION OF THE DRAWINGS

In the figures the same elements and apparatuses or elements and apparatuses with the same functions are provided with the same reference characters. Furthermore the number of method steps serves to provide clarity and, unless stated otherwise, is not intended to imply a specific time sequence. Thus a number of method steps can be carried out at the same time. Furthermore different forms of embodiment are generally able to be combined with one another in any given manner.

In the figures:

FIG. 1 shows a schematic illustration for explanation of direct x-ray conversion;

FIG. 2 shows a schematic illustration for explanation of indirect x-ray conversion;

FIG. 3 shows a cross-sectional view of a detection apparatus in accordance with a form of embodiment of the present invention;

FIG. 4 shows a crystal lattice of a perovskite;

FIG. 5 shows the dependence of the mass attenuation on the x-ray energy for a plurality of examples of perovskites;

FIG. 6 shows a cross-sectional view of a detection apparatus in accordance with a form of embodiment of the present invention;

FIGS. 7 to 9 show schematic circuit diagrams of detection apparatuses in accordance with forms of embodiment of the invention;

FIG. 10 shows a cross-sectional view of a detection apparatus in accordance with a form of embodiment of the present invention; and

FIG. 11 shows a flow diagram for explanation of a manufacturing method for a detection apparatus in accordance with a form of embodiment.

### DETAILED DESCRIPTION OF THE EXAMPLE EMBODIMENTS

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various example embodiments will now be described more fully with reference to the accompanying drawings in which only some example embodiments are shown. Specific structural and functional details disclosed herein are merely representative for purposes of describing example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated. The present invention, however, may be embodied in many alternate forms and should not be construed as limited to only the example embodiments set forth herein.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “connected,” “engaged,” “interfaced,” and “coupled.” Unless explicitly described as being “direct,” when a relationship between first and second elements is described in the above disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “exemplary” is intended to refer to an example or illustration.

When an element is referred to as being “on,” “connected to,” “coupled to,” or “adjacent to,” another element, the element may be directly on, connected to, coupled to, or adjacent to, the other element, or one or more other intervening elements may be present. In contrast, when an element is referred to as being “directly on,” “directly connected to,” “directly coupled to,” or “immediately adjacent to,” another element there are no intervening elements present.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Before discussing example embodiments in more detail, it is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments of the present invention. This invention may, however, be embodied in many alternate forms and should not be construed as limited to only the embodiments set forth herein.

Units and/or devices according to one or more example embodiments may be implemented using hardware, software, and/or a combination thereof. For example, hardware devices may be implemented using processing circuity such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or porcessors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one embodiment of the invention relates to the non-transitory computer-readable storage medium including electronically readable control information (procesor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

The detection apparatus advantageously provides at least two layers with perovskites, which are suitable for detection of x-ray radiation. If the upper layer and the lower layer are embodied differently, then in this way the detection apparatus allows the evaluation of different energy ranges. The detection apparatus is thus able to be used for dual x-ray absorptiometry, wherein however a very compact structure is possible at the same time. Thus the middle electrode serves as a common electrode together with the lower or upper electrode. A stacked structure will thus be made possible, through which a number of absorption layers can be combined. It is no longer necessary to use a number of x-ray detectors independent of one another. The detection apparatus is further characterized by its simple and low-cost method of manufacture. It should be pointed out that a dual x-ray contrast can also be determined if the upper and the lower layer consist of the same material. However the embodiment with different materials is preferred however, since this enables a higher energy discrimination to be achieved.

In accordance with a preferred form of embodiment, the second perovskite has a higher energy absorption rate in a first energy range than the first perovskite. In a second energy range, which is higher than the first energy range, i.e. consequently comprises higher energies, the first perovskite has a higher absorption rate than the second perovskite. The upper and lower layer thus differ in their absorption characteristics, and are thus embodied for detection of x-ray radiation in different energy ranges. If the x-ray radiation first enters the upper layer for example, x-ray radiation will preferably be absorbed in the first energy range. Subsequently the remaining x-ray radiation enters the lower layer and will preferably be absorbed there in the second energy range. Especially preferably in this case the first energy range has a lower energy than the second energy range, since lower-energy x-ray radiation will generally be more strongly absorbed and the accordingly designed absorption layer should be facing towards the radiation source.

Through the use of different perovskites it is possible to minimize the layer thickness of the upper or lower layer. On the one hand this makes a more compact structure possible. This also enables the necessary strength of the voltage applied to the electrodes to be reduced. A smaller layer thickness also provides an advantage to the effect that the path of the charge carriers, which said carriers must cover to the electrodes, will be reduced, through which losses by recombination can be reduced. The accuracy of the detection apparatus will thus be increased.

In accordance with a further form of embodiment, the first energy range lies between 15 and 30 kiloelectron volts (keV). The second perovskite thus absorbs energy-poor or soft x-ray radiation especially well.

In accordance with a further form of embodiment, the second energy range lies between 50 and 120 keV. The first perovskite thus absorbs energy-rich or hard x-ray radiation especially well.

In accordance with a further form of embodiment of the detection apparatus, a thickness of the upper layer is smaller than a thickness of the lower layer. If x-ray radiation strikes the detection apparatus, then the x-ray radiation preferably first passes through the upper electrodes into the upper layer and interacts here with the second perovskite. Thus preferably soft x-ray radiation, meaning x-ray radiation with lower energy, will be absorbed and detected in the upper layer. Subsequently the remaining x-ray radiation enters through the middle electrode and arrives in the lower layer with the first perovskite and will be absorbed and also detected there. Thus the upper layer is used for detection of soft x-ray radiation, meaning detection of x-ray radiation with a lower energy, while the lower layer is used for detection of hard x-ray radiation, meaning detection of x-ray radiation with a higher energy.

In accordance with a further form of embodiment of the detection apparatus, the upper electrode and/or the lower electrode are structured and are connected via a matrix circuit to the evaluation device, wherein the evaluation device is embodied to detect the interaction of the x-ray radiation with the first perovskite and/or the interaction of x-ray radiation with the second perovskite in a spatially-resolved manner. The pixels of the upper and lower layer can be the same size in such cases, but can also be different sizes.

In accordance with a further form of embodiment, the evaluation device has an array of transistors and an analog-to-digital converter, so that the charge carriers can be digitized in a spatially-resolved manner in accordance with the pixelization of the electrodes.

The spatially-resolved x-ray image of the upper detector and of the lower detector can be registered to one another with known algorithms of the prior art and the combined image can be presented as a colored x-ray image.

In accordance with a preferred form of embodiment of the detection apparatus, a coating with at least one hole-blocking material and/or at least one electron-blocking material is embodied between the upper layer and the upper electrode and/or between the upper layer and the middle electrode, and/or between the lower layer and the middle electrode and/or between the lower layer and the lower electrode. This enables the dark current or basic or leakage current to be reduced, which also flows in the absence of x-ray radiation between the middle electrode and the upper electrode or between the middle electrode and the lower electrode. This enables the noise to be reduced and the accuracy of the detection apparatus to be improved. This is of advantage in particular for use in the medical field, since the dose used can thus be reduced and the patient will be subjected to a lower radiation load.

In accordance with a preferred form of embodiment of the detection apparatus, the upper electrode and/or the lower electrode are structured and are coupled to the evaluation device via a matrix circuit, wherein the evaluation device is embodied to detect the interaction of x-ray radiation with the first perovskite and/or the interaction of x-ray radiation with the second perovskite in a spatially-resolved manner.

In accordance with a preferred form of embodiment of the detection apparatus, the evaluation device has a plurality of evaluation units, wherein the upper electrode and/or the lower electrode are structured and have a plurality of upper electrode elements (pixels) or lower electrode elements (pixels), which are coupled to one of the plurality of evaluation units in each case. This enables the electrode elements to be read out simultaneously and at a higher clock rate.

In accordance with a further form of embodiment of the inventive detection apparatus, the middle electrode includes an x-ray filter. The x-ray filter here is a filter, which is designed to filter out a predetermined energy range of the x-ray radiation. Thus x-ray radiation, which still remains after absorption in the upper layer is filtered before its passage to the lower layer. For example a transition range between hard and soft radiation can be filtered out so that the contrast will be increased.

In accordance with a further form of embodiment of the inventive manufacturing method, the substrate comprises the lower electrode. The detection apparatus will thus be manufactured in a compact manner.

In accordance with a further form of embodiment of the manufacturing method the arrangement of the middle electrode between the upper layer and the lower layer comprises the arrangement of a lower conductive layer on the lower layer. An upper conductive layer will further be arranged on the upper layer. Finally the lower conductive layer will be connected to the upper conductive layer via an intermediate conductive layer, wherein the middle electrode comprises the lower conductive layer, the intermediate conductive layer and the upper conductive layer. This form of embodiment has the advantage that the detection apparatus can be manufactured parallelized. Thus lower and upper halves of the detection apparatus will be manufactured independently of one another, which each comprise the lower or upper electrode and lower or upper layer as well as the lower or upper conductive layer. The upper part of the detection apparatus will subsequently be connected via the intermediate conductive layer to the lower part of the detection apparatus.

In accordance with a preferred development of the manufacturing method, the upper and/or the lower layer will be compressed by heating them up and/or by application of pressure. This enables a more compact and more homogeneous layout to be achieved.

In accordance with a preferred development of the manufacturing method a coating with at least one hole-blocking material and/or at least one electron-blocking material will be embodied between the upper layer and the upper electrode and/or between the upper layer and the middle electrode, and/or between the lower layer and the middle electrode and/or between the lower layer and the lower electrode.

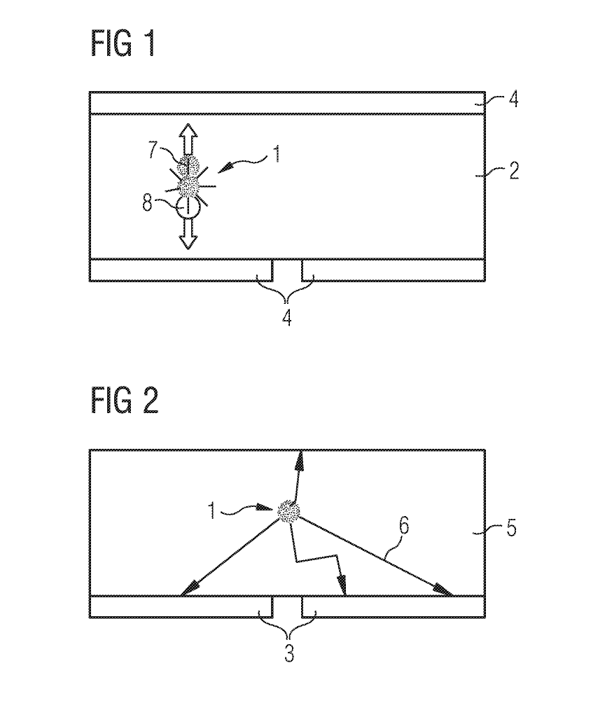

X-ray detectors are usually based on two different principles, namely direct x-ray conversion and also indirect x-ray conversion. With the direct x-ray conversion illustrated in FIG. 1 an x-ray photon 1 will be absorbed within a semiconductor 2 and through conversion of the energy of the x-ray photon 1 an electron-hole pair 7, 8 will be created. An electrical field will be applied between electrodes 4, so that the electron 7 moves to an electrode 4 and the hole 8 to an opposite electrode 4. The created electron-hole pair 7, 8 can thus be read out at the electrodes 4. Amorphous selenium will be used here for example. Silicon diodes are also suitable for detection of direct x-ray conversion.

With the indirect x-ray conversion illustrated in FIG. 2 the x-ray photon 1 will be absorbed into a scintillator layer 5, which emits radiation 6 with lower energy, which can be detected with photo detectors 3, for example photodiodes.

The scintillator layer comprises for example Gd₂O₂S or CsI with different doping materials such as terbium, thallium, europium, etc.

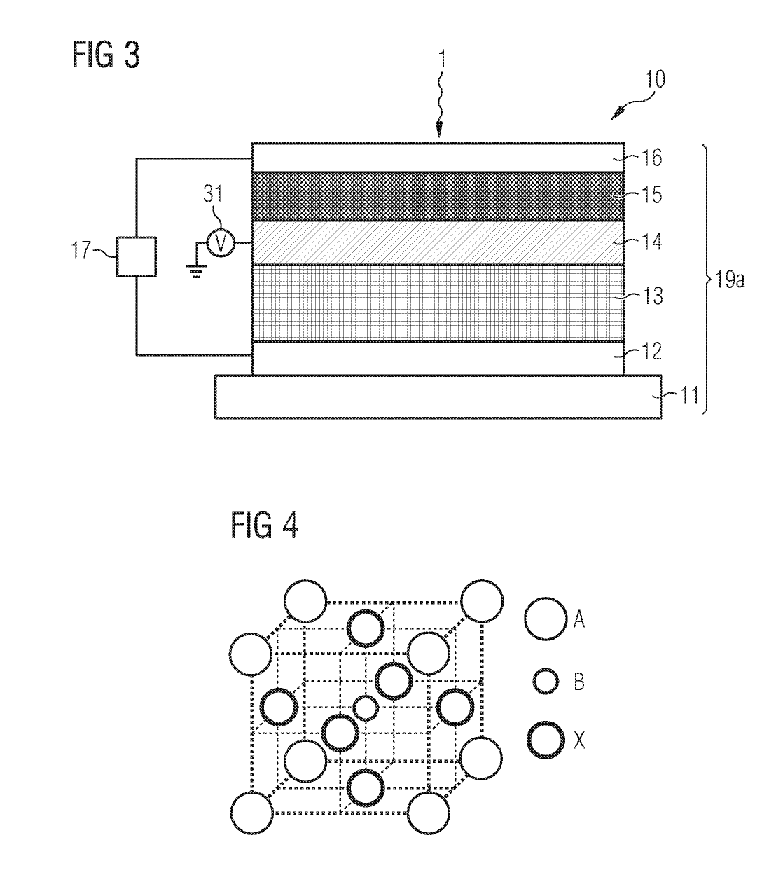

In FIG. 3 a detection apparatus 10 for detection of x-ray radiation in accordance with a form of embodiment of the present invention is illustrated. The detection apparatus 10 has a lower layer 13, which features a first perovskite. Preferably the lower layer 13 consists entirely of the first perovskite.

The first perovskite is preferably present as a crystal and can comprise materials of type ABX₃ and/or AB₂X₄. A typical crystal lattice of a perovskite of type ABX₃ is illustrated in FIG. 4.

Here for example A is at least a univalent, bivalent and/or trivalent, positively-charged element from the 4th period of the periodic system onwards or is a mixture thereof, this also comprises the 5th, 6th and 7th periods including the lanthanoids and actinoids, wherein the 4th period of the periodic system begins with K and comprises the transition metals from Sc onwards. Preferably, in the formulae above, A is one of the elements Sn, Ba, Pb, Bi or mixtures thereof.

B represents an example of a univalent cation, of which the volume parameter for the respective element A satisfies the perovskite lattice formation. The corresponding volume parameters for the perovskite lattice formation are sufficiently known here, both theoretically and also for example from x-ray crystallographic investigations, as are the volume parameters of univalent cations and the cations defined under A. Thus the corresponding univalent cation B can be suitably determined after determination of the elements A and if necessary X, for example on the basis of computer models as well as possibly simple trials.

In the above formulae B preferably represents a univalent, positively-charged carbon compound containing amino groups, wherein a carbon compound is a compound having at least one carbon atom and thus comprises organic and also inorganic compounds. In accordance with specific forms of embodiment, B is selected from the group consisting of amidinium ions, guanidinium ions, isothiuronium ions, formamidinium ions, as well as primary, secondary, tertiary and/or quarternary organic ammonium ions, which especially preferably have 1 to 10 carbon atoms, especially 1 to 4 carbon atoms, wherein this can involve aliphatic, olefinic, cycloaliphatic and/or aromatic carbon compounds.

X is for example selected from the anions of halogenides and pseudohalogenides and is preferably selected from the anions of chloride, bromide and iodide, as well as mixtures of the same. Thus for example different halogenide ions can also be contained in the perovskites, however in accordance with specific forms of embodiment, only one halogenide ion, such as iodide for example, is contained therein.

Materials of the general formula ABX₃ and AB₂X₄ can especially crystallize in the perovskite lattice, when A is a bivalent element from the fourth period onwards in the PSE, B is any given univalent cation, of which the volume parameters are sufficient for the respective element A for perovskite lattice formation, and X corresponds to the halogenide anions iodide, bromide or chloride or mixtures thereof. In accordance with an embodiment of the invention it is not excluded for perovskites of both the general formula ABX₃ and also the general formula AB₂X₄ to be present in the detection layer, however only perovskites in accordance with one of the two formulae can be present, for example ABX₃.

For example the following materials mixed in a molar ratio are suitable as perovskites:

CH₃—NH₃I:PbI₂═Pb CH₃NH₃ I₃

CH₃—CH₂—NH₃I:PbI₂═Pb CH₃NH₃ I₃

HO—CH₂—CH₂—NH₃:PbI₂═Pb HO—CH₂—CH₂—NH₃ I₃

Ph-CH₂—CH₂—NH₃I:PbI₂═Pb (Ph-CH₂—CH₂—NH₃)₂ I₄

The known material, which will be formed from methylammonium-iodide and lead-II-iodide (MAPbI₃) is valid as an intrinsic or undoped perovskite (i-perovskite) for example.

By variation of the substitution pattern of the ammonium component the formed perovskite can be designed by a donor function as more strongly p-conducting or by an acceptor function as more strongly n-conducting.

The first perovskite can thus also be obtained from n- and p-doped perovskite powders (n-perovskite or p-perovskite).

The first perovskite can be undoped or doped and can occur homogeneously or heterogeneously mono- or polycrystalline.

Materials, molecules and methods which make possible a doping of perovskites are described as follows for example: Salt mixtures that crystallize in a perovskite structure are determined by their molecular geometry. These heavy metal/salt mixtures, which crystallize in the perovskite lattice, are a prerequisite for the use of such materials in detectors, such as x-ray detectors.

Ammonium salts as B (comprising halogenides such as Cl⁻, Br⁻, I⁻), which increase the p-conductivity, are e.g. 2-methoxyethyl ammonium halogenide, 4-methoxybenzyl ammonium halogenide, amidinium halogenide, S-methylthiuronium halogenide, N,N-dimethyl hydrazinium halogenide, N,N-diphenyl hydrazinium halogenide, phenyl hydrazinium halogenide and methyl hydrazinium haligenide.

Ammonium salts as B (comprising halogenides such as Cl⁻, Br⁻, I⁻), which increase the n-conductivity, are e.g. cyanomethyl ammonium halogenide, 2-cyanoethyl ammonium halogenide and 4-cyanobenzyl ammonium halogenide.

Furthermore n- or p-perovskites also comprise other donor or acceptor functionalized salt structures, which fulfill the geometry requirements of perovskites and crystallize with the cations, for example heavy metal ions, in the perovskite crystal structure.

The detection apparatus 10 further comprises an upper layer 15, which features at least one second perovskite. The second perovskite can be one of the perovskites described above. The first perovskite preferably differs from the second perovskite in its absorption characteristics.

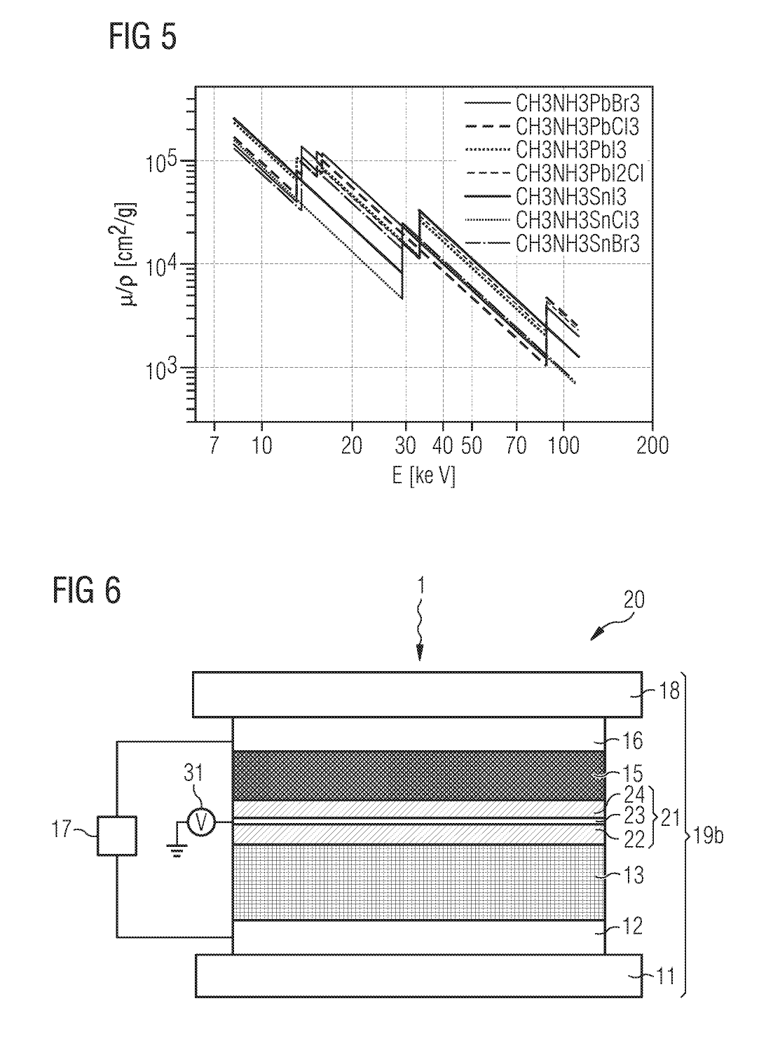

In FIG. 5 the mass attenuation coefficient μ/ρ for different perovskites is plotted as a function of the energy E of the x-ray radiation. It can be seen here that different perovskites absorb very differently in different energy ranges or energy windows.

Preferably the second perovskite, in a first energy range, exhibits a higher absorption rate than the first perovskite. The first energy range lies for example between 15 and 30 keV, preferably in the range of 20 to 30 keV. The second perovskite thus absorbs soft or energy-poor radiation more strongly than the first perovskite.

The first perovskite preferably also exhibits a higher absorption rate than the second perovskite in a second energy range, which is higher than the first energy range. The second energy range lies for example between 50 and 120 keV, preferably between 70 and 100 keV. The first perovskite thus absorbs hard or energy-rich radiation more strongly than the second perovskite.

Preferably the second perovskite is CH₃NH₃PbBr₃ here and the first perovskite is preferably CH₃NH₃SnI₃.

Furthermore a middle electrode 14 is arranged between the upper layer and the lower layer 13. Finally an upper electrode 16 is arranged on a side of the upper layer 15 facing away from the middle electrode 14 and a lower electrode 12 is arranged on a side of the lower layer 13 facing away from the middle electrode 14. Metals, for example Au, Ag, Pt, Cu, Al, Cr, Mo, Pb, W etc., or mixtures or alloys consisting of metals can be used here as electrode materials of the upper electrode 16, middle electrode 14 and lower electrode 12. Conductive oxides or metal oxides, for example ITO, AZO and/or conductive polymers, for example PEDOT or PEDOT:PSS, can also be used as electrode materials. The lower electrode 12 is arranged on an optional lower substrate 11.

The lower substrate 11, the lower electrode 12, the lower layer 13, the middle electrode 14, the upper layer 15 and the upper electrode 16 form a first layer structure 19a. The upper electrode 16 preferably forms an entry side for the x-ray radiation 1, meaning that the x-ray radiation first enters through the upper electrode 16 into the upper layer 15, interacts there at least partly with the second perovskite, and subsequently enters through the middle electrode 14 into the lower layer 13, and interacts there with the first perovskite.

The detection apparatus 10 further has a voltage source 31, which is embodied for applying a first voltage or second voltage between the lower electrode 12 and the middle electrode 14 or the upper electrode 16 and the middle electrode 14.

The detection apparatus 10 further comprises an evaluation device 17, which is coupled to the upper layer 15 via the upper electrode 16 and to the lower layer 13 via the lower electrode 12 and the lower substrate 11. The evaluation device 17 is embodied to detect an interaction of x-ray radiation with the first perovskite in the lower layer 13 and an interaction of x-ray radiation with the second perovskite in the upper layer 15. The evaluation device 17 can be embodied here to measure a current between the upper electrode 16 and the middle electrode 14 and/or the middle electrode 14 and the lower electrode 12 and to detect the interaction on the basis of the current. The current can possibly have arisen through the direct conversion described above.

In accordance with a further form of embodiment a thickness of the upper layer 15 is smaller than a thickness of the lower layer 13.

Preferably the upper layer 15 or the lower layer 13 is designed such that a predetermined energy range will be absorbed by at least 50%, preferably by at least 70%, mostly preferably at least 90%. For example a layer thickness of the upper layer 15, which is embodied for absorption of soft radiation, is between 10 μm and 100 μm. Preferably a layer thickness of the lower layer 13, which is embodied for absorption of hard radiation, is between 100 μm and 1000 μm.

In accordance with a further form of embodiment, the middle electrode 14 has an x-ray filter. This enables certain energy ranges of the x-ray radiation to be filtered out and thus the contrast between images that will be created on the basis of the x-ray radiation detected in the upper layer 15, and images that will be created on the basis of the x-ray radiation detected in the lower layer 13, to be increase. For example the x-ray filter can be embodied to filter x-ray radiation in an energy range below 50 keV. For this purpose the middle electrode 14 can be coated with an additional filtering layer or can be embodied from a filtering material.

Illustrated in FIG. 6 is a detection apparatus 20 in accordance with a further form of embodiment of the present invention. In addition here the upper electrode 16 is arranged on an upper substrate 18. Furthermore the middle electrode 21 comprises an upper conductive layer 24 arranged on the upper layer 15, a lower conductive layer 22 arranged on the lower layer 13 and an intermediate conductive layer 23 connecting the upper conductive layer 24 and the lower conductive layer 22. The upper conductive layer 22, the intermediate conductive layer 23 and the lower conductive layer 22 can consist here of the same material or of different materials, in particular of one of the electrode materials described above.

The lower substrate 11, the lower electrode 12, the lower layer 13, the middle electrode 21, the upper layer 15, the upper electrode 16 and the upper substrate 18 form a second layer structure 19b.

In accordance with a further form of embodiment, at least one layer with at least one hole-blocking material and/or at least one electron-blocking material is embodied in the layer structure 19 between the lower layer 13 and the lower electrode 12 and/or between the upper layer 15 and the upper electrode 16 and/or between the lower layer 13 and the middle electrode and/or between the upper layer 15 and the middle electrode 14. In particular at least one of the electrodes 12, 14, 16 can be coated. Furthermore at least one of the electrodes 12, 14, 16 can be coated from both sides, wherein the same or different materials can be used.

Organic semiconductors, in particular PCBMs, can be used as hole-blocking or electron-conduction material. Organic semiconductors, such as PEDOT:PSS, P3HT, MDMO-PPV, MEH-PPV or TFB can be used as electron-blocking or hole-conducting material. The transition from the active upper layer 15 or lower layer 13 to the upper electrode 16 or lower electrode 12 or to the middle electrode 14 and thus the contacting will be improved by this. In addition the injection of charge carriers from the electrodes will be reduced and thus the leakage current or dark current reduced in the blocking direction.

Preferably one or more intermediate layers comprising p-perovskites and/or n-perovskites and/or i-perovskites can be arranged between at least one electrode and the lower layer 13 or upper layer 15. In particular p-n transitions can be embodied in order to provide a hole-blocking or electron-blocking material in this way. The number, arrangement and thickness of the intermediate layers is not restricted.

If the electrode 12, 14, 16, on which the layer is arranged involves an anode, then preferably an electron-blocking material will be used and if the electrode 12, 14, 16 involves a cathode, then preferably a hole-blocking material will be used.

In accordance with a further form of embodiment, contacts can be coated with electron-blocking material and/or a hole-blocking material in such a way that the sequence of layers acquires the function of an x-ray diode. An x-ray diode here refers to a structure with a method of functioning that corresponds to the method of functioning of a photodiode under illumination with visible light. On application of a positive voltage to the x-ray diode a large current can flow, while on application of a negative voltage the x-ray diode blocks and there is only evidence of a low dark current. By the illumination of the x-ray diode with x-ray radiation charge carriers are created in the x-ray diode and the blocking current increases. The measure of the increase is very largely proportional to the intensity of the incident x-ray radiation. The rectification or the blocking behavior of the x-ray diode can thus be improved.

An x-ray diode can be formed for example by the upper layer 15, the upper electrode 16, as well as a coating embodied between the upper layer 15 and the upper electrode 16. The coating consists here of an electron-blocking material and/or a hole-blocking material, so the current in the blocking direction will be reduced. The upper layer 15, which comprises the second perovskite, is preferably embodied electrically-conductive here.

An x-ray diode can also be formed by the lower layer 13, the lower electrode 12, as well as by a coating embodied between the lower layer 13 and the lower electrode 12.

The lower electrode 12, the middle electrode 14 and the upper electrode 16 are thus preferably coated such that a rectifying contact is put into effect.

For example the middle electrode 14 can be designed as an anode and be coated on both sides with an electron-blocking material (e.g. TFB). In this way the injection of electrons into the lower layer 13 and the upper layer 15 will be suppressed. Also in this example the upper electrode 16 and the lower electrode 12 each assumes the function of the cathode and is coated in each case with a hole-blocking material, e.g. PCBM. Through this the injection of holes from the cathode into the lower layer 13 and the upper layer 15 will be suppressed.

In accordance with a further form of embodiment, contacts can be coated with an electron-blocking material and/or a hole-blocking material in such a way that the layer sequence obtains the method of functioning of an x-ray conductor. The term x-ray conductor here refers to a structure with a way of functioning that corresponds to the way of functioning of a photoconductor or photoresistor. Regardless of the polarity of the applied voltage only a low dark current flows in the x-ray conductor. The current in the x-ray conductor increases through irradiation with x-ray photons. The increase can be used for quantification of the incident x-ray radiation.

Such an x-ray conductor can be formed for example by the upper layer 15 and the upper electrode 16, wherein the upper layer 15 is preferably highly resistive, consequently exhibits a high electrical resistance. An x-ray conductor can also be formed by the lower layer 13 and the lower electrode 12, wherein the lower layer 13 is preferably highly resistive, consequently exhibits a high electrical resistance.

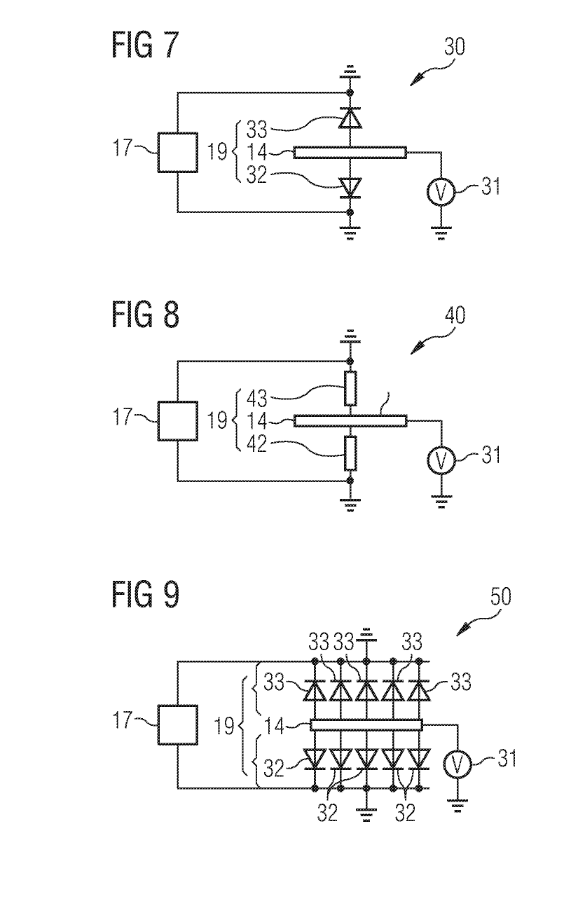

Schematic circuit diagrams of detection apparatuses 30, 40, 50 in accordance with forms of embodiment are illustrated in FIGS. 7, 8 and 9.

The detection apparatus 30 illustrated in FIG. 7 has a layer structure 19, which features the middle electrode 14 and also an upper x-ray diode 33 and a lower x-ray diode 32. The upper x-ray diode 33 can, as described above, consist of the upper layer 15, the upper electrode 16, as well as a coating embodied between the upper layer 15 and the upper electrode 16. The lower x-ray diode 32 can consist of the lower layer 13, the lower electrode 12, as well as a coating embodied between the lower layer 13 and the lower electrode 12.

The circuit symbols for the x-ray diodes 33, 32 are only to be understood as schematic here and represent the corresponding layer structure.

The upper x-ray diode 33 is embodied to transport charge carriers, which arise as a result of interaction of x-ray radiation with the second perovskite of the upper layer 15, to an evaluation device 17. The lower x-ray diode 32 is embodied to transport charge carriers, which arise as a result of interaction of x-ray radiation with the first perovskite in the lower layer 13, to the evaluation device 17. The evaluation device 17 is embodied to detect an interaction of x-ray radiation with the first perovskite and an interaction von x-ray radiation with the second perovskite. The detection apparatus 30 is thus embodied as a dual x-ray detector.

Illustrated in FIG. 8 is a detection apparatus 40 in accordance with a further form of embodiment. Instead of the upper x-ray diode 33 and the lower x-ray diode 32 of the detection apparatus 30 illustrated in FIG. 7, the layer structure 19 comprises an upper x-ray conductor 43 and a lower x-ray conductor 42, which are coupled to a corresponding evaluation device 17. The circuit symbols for x-ray conductors 43, 42 are once again only to be understood as schematic and stand for the corresponding layer structure.

Illustrated in FIG. 9 is a detection apparatus 50 in accordance with a further form of embodiment. Here the lower electrode 12 and the upper electrode 16 are structured, so that together with the large-surface middle electrode 14 and the large-surface upper layer 15 or lower layer 13, a plurality of lower x-ray diodes 32 and a plurality of upper x-ray diodes 33 is produced.

An evaluation device 17 in this embodiment is designed so that it can read out the lower x-ray diodes 32 and the upper x-ray diodes 33 independently of one another, consequently can detect the interaction of the x-ray radiation with the first perovskite and the interaction of x-ray radiation with the second perovskite in a spatially-resolved manner. Preferably the upper electrode 16 and the lower electrode 12 are connected via a matrix circuit to the evaluation device 17. The detection apparatus 50 is thus designed to detect the x-ray radiation, which interacts with the second perovskite in the upper layer 15 or with the first perovskite in the lower layer 13, in a spatially-resolved manner. Through this the detection device 50 is embodied for an imaging method. While the arrangement of the lower x-ray diodes 32 or upper x-ray diodes 33 is illustrated one-dimensionally, the lower x-ray diodes 32 or upper x-ray diodes 33 are preferably arranged two-dimensionally, especially in an array shape, on the layer structure 19, in order thereby to be able to generate a two-dimensional image.

Instead of the plurality of the lower x-ray diodes 32 and the plurality of the upper x-ray diodes 33, lower x-ray conductor 42 or upper x-ray conductor 43 can also be used.

In accordance with a form of embodiment the detection apparatus 50 comprises a plurality of separately contactable upper electrodes 16 or lower electrodes 12. These can preferably be arranged pixelated or in the form of an array. Here each of the upper x-ray diodes 33 is connected to a separate upper evaluation device and each of the lower x-ray diodes 32 to a separate lower evaluation device. This configuration is used for example in a computed tomograph, in which the generated charges must be detected in each pixel simultaneously and with a high clock rate.

In accordance with a further form of embodiment the lower substrate 11 or the upper substrate 18 can have pixelated contacts. The lower substrate 11 or the upper substrate 18 can have a TFT array, which can consist of metal-oxidic materials on a glass plate or flexible polymer foil for example. The pixelated contacts can also be connected to a TFT matrix (TFT array), to ASICs or discrete circuits, in order to make a sequential readout of the individual pixels possible.

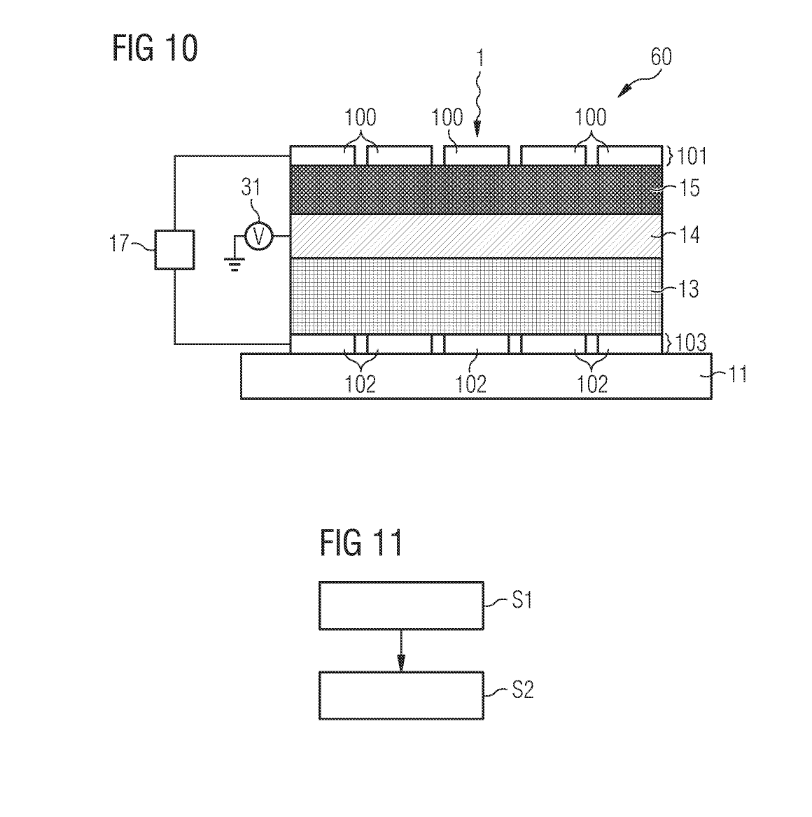

FIG. 10 shows a detection apparatus 60 in accordance with a further form of embodiment of the invention. The upper electrode 101 and also the lower electrode 103 are structured here, so that a plurality of contactable upper electrode elements 100 or lower electrode elements 102 (pixels) preferably arranged in the form of an array will be formed. Preferably the detection apparatus 60 in its turn can have additional coatings. In particular the upper x-ray diodes 33 and lower x-ray diodes 32 illustrated in FIG. 9 can be formed in this way.

In accordance with a further form of embodiment, the evaluation device 17 can feature a plurality of evaluation units here. Each of the upper electrode elements 100 or lower electrode elements 102 is coupled to one of the evaluation units. The evaluation units can preferably read out the pixels separately, i.e. detect an interaction of x-ray radiation with the first perovskite or an interaction of x-ray radiation with the second perovskite in the area of the corresponding upper electrode element 100 or lower electrode element 102 and create corresponding data. The created data can preferably be evaluated subsequently by the evaluation device 17 combined a together.

Illustrated in FIG. 11 is a flow diagram for explanation of a manufacturing method for a detection apparatus for detection of x-ray radiation in accordance with form of embodiment of the invention. In a first step S1 a lower layer 13, which features at least one first perovskite, will be arranged on a lower substrate 11. Here the arrangement of the lower layer 13 can comprise a provision and distribution of a first powder, which features the first perovskite.

In a second step S2 a middle electrode will be arranged between an upper layer 15 and the lower layer 13, wherein the upper layer 15 features at least one second perovskite. The arrangement of the upper layer 15 can include the provision and distribution of a second powder, which features the second perovskite. Preferably the second powder will be provided and distributed on the middle electrode 14.

An upper electrode 16 will be arranged here on one side of the upper layer, which faces away from the middle electrode, and a lower electrode will be arranged here on one side of the lower layer 13, which faces away from the middle electrode.

The upper layer 15 and/or the lower layer 13 can be compressed here by heating up and/or exerting pressure in a sinter step either before or after the arrangement of the upper electrode 16 and the lower electrode 12. The temperature of the sinter step lies between 30 and 300° C., preferably between 50 and 200° C. for example. The applied pressure lies between 0.1 and 10,000 MPa, preferably between 0.5 and 200 MPa and especially preferably between 1 and 50 MPa for example. The sinter time lies between 1 s and 30 min and especially preferably between 5 and 10 min for example.

This enables a detection apparatus 10 shown in FIG. 3 for example.

In accordance with a further form of embodiment a coating with at least one hole-blocking material and/or at least one electron-blocking material will be embodied between the upper layer 15 and the upper electrode 16, and/or between the upper layer 14 and the middle electrode 14, and/or between the lower layer 13 and the middle electrode 14, and/or between the lower layer 13 and the lower electrode 12.

In accordance with a further form of embodiment the arrangement of the middle electrode 21 between the upper layer 15 and the lower layer 13 comprises a number of steps. Thus first a lower conductive layer 22 will be arranged on the lower layer 13. Furthermore an upper conductive layer 24 will be arranged on the upper layer 15. The lower conductive layer 22 will be connected to the upper conductive layer 22 via an intermediate conductive layer 23, wherein the middle electrode 21 comprises the lower conductive layer 22, the intermediate conductive layer 23 and the upper conductive layer 24.

In this way for example the detection apparatus 20 illustrated in FIG. 6 can be manufactured. For example on the one hand, independently of one another, the lower electrode 12 can be arranged on the lower substrate 11, the lower layer 13 on the lower substrate 12 and the lower conductive layer 22 on the lower layer 13, on the other hand the upper electrode 16 can be arranged on the upper substrate 18, the upper layer 15 on the upper electrode 16 and the upper conductive layer 24 on the upper layer 15. These elements manufactured independently of one another can then be joined to one another via the intermediate conductive layer 23, especially by gluing or by a heating step.

In accordance with a further form of embodiment, the lower substrate 11 and/or the upper substrate 18 can be removed again in a further method step and if necessary replaced by another substrate, for example a TFT array.

In accordance with a further form of embodiment the middle electrode will be used as a substrate. For example a sheet of metal can be used as the middle electrode, which preferably has a thickness of a few millimeters, and thus can still simultaneously assume the function of an x-ray filter.

The invention is not restricted to the forms of embodiment described. In particular any given plurality of perovskite layers can be stacked above one another, wherein at least one electrode will be arranged between two perovskite layers in each case.

An embodiment of the invention further comprises a method for detection of x-ray radiation via one of the detection apparatuses illustrated above. Here the evaluation device detects x-ray radiation on the basis of an interaction of the x-ray radiation with the first perovskite and/or the second perovskite. The detection apparatus can be embodied here for detection of the presence of x-ray radiation. The detection apparatus can however also be embodied for creation of x-ray images, i.e. for the detection of a spatially-resolved image, for example via a plurality of x-ray diodes 32, 33 or x-ray conductors 42, 43.

The patent claims of the application are formulation proposals without prejudice for obtaining more extensive patent protection. The applicant reserves the right to claim even further combinations of features previously disclosed only in the description and/or drawings.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

None of the elements recited in the claims are intended to be a means-plus-function element within the meaning of 35 U.S.C. §112(f) unless an element is expressly recited using the phrase “means for” or, in the case of a method claim, using the phrases “operation for” or “step for.”

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A detection apparatus for detection of x-ray radiation, the detection apparatus comprising:
a lower layer, arranged between a lower electrode and a middle electrode, the lower layer including at least one first perovskite and a first voltage being appliable between the lower electrode and the middle electrode;
an upper layer, arranged between an upper electrode and the middle electrode, the upper layer including at least one second perovskite and a second voltage being appliable between the upper electrode and the middle electrode; and
an evaluation device, coupled to the upper layer and the lower layer, embodied to detect an interaction of x-ray radiation with the first perovskite and an interaction of x-ray radiation with the second perovskite.

2. The detection apparatus of claim 1, wherein the second perovskite, in a first energy range, has a relatively higher absorption rate than the first perovskite; and wherein the first perovskite, in a second energy range, relatively higher than the first energy range, has a relatively higher absorption rate than the second perovskite.

3. The detection apparatus of claim 2, wherein the first energy range lies between 15 and 30 keV.

4. The detection apparatus of claim 3, wherein the second energy range lies between 50 and 120 keV.

5. The detection apparatus of claim 1, wherein a thickness of the upper layer is relatively smaller than a thickness of the lower layer.

6. The detection apparatus of claim 1, wherein a coating including at least one of at least one hole-blocking material and at least one electron-blocking material is embodied between at least one of the upper layer and the upper electrode, between the upper layer and the middle electrode, between the lower layer and the middle electrode, and between the lower layer and the lower electrode.

7. The detection apparatus of claim 1, wherein at least one of the upper electrode and the lower electrode are structured and are coupled via a matrix circuit to the evaluation device, and wherein the evaluation device is embodied to detect at least one of interaction of the x-ray radiation with the first perovskite and interaction of x-ray radiation with the second perovskite in a spatially-resolved manner.

8. The detection apparatus of claim 1, wherein the evaluation device includes a plurality of evaluation units, and wherein at least one of the upper electrode and the lower electrode are structured and include a plurality of upper electrode elements or lower electrode elements, each respectively coupled to respective ones of a plurality of evaluation units.

9. The detection apparatus of claim 1, wherein the middle electrode includes an x-ray filter.

10. A manufacturing method for a detection apparatus for detection of x-ray radiation, comprising:
arranging a lower layer, including at least one first perovskite, on a substrate;
arranging a middle electrode between the lower layer and an upper layer, the upper layer including at least one second perovskite;
arranging an upper electrode on a side of the upper layer facing away from the middle electrode; and
arranging a lower electrode on a side of the lower layer facing away from the middle electrode.

11. The manufacturing method of claim 10, wherein the substrate comprises the lower electrode.

12. The manufacturing method of claim 10, wherein the arrangement of the middle electrode between the upper layer and the lower layer comprises:
arranging a lower conductive layer on the lower layer;
arranging an upper conductive layer on the upper layer; and
connecting the lower conductive layer to the upper conductive layer via an intermediate conductive layer, the middle electrode including the lower conductive layer, the intermediate conductive layer and the upper conductive layer.

13. The manufacturing method of claim 10, wherein at least one of the upper layer and the lower layer are compressable by at least one of heating and exerting pressure.

14. The manufacturing method of claim 10, wherein a coating including at least one of at least one hole-blocking material and at least one electron-blocking material is embodied at least one of between the upper layer and the upper electrode, and between the upper layer and the middle electrode, between the lower layer and the middle electrode, and between the lower layer and the lower electrode.

15. A method for detection of x-ray radiation via a detection apparatus comprising a lower layer, arranged between a lower electrode and a middle electrode, the lower layer including at least one first perovskite and a first voltage being appliable between the lower electrode and the middle electrode; an upper layer, arranged between an upper electrode and the middle electrode, the upper layer including at least one second perovskite and a second voltage being appliable between the upper electrode and the middle electrode; and an evaluation device, coupled to the upper layer and the lower layer, embodied to detect an interaction of x-ray radiation with the first perovskite and an interaction of x-ray radiation with the second perovskite, the method comprising:
detecting, via the evaluation device, x-ray radiation on the basis of an interaction of the x-ray radiation with at least one of the first perovskite and the second perovskite; and
creating x-ray images.

16. The detection apparatus of claim 2, wherein the second energy range lies between 50 and 120 keV.

17. The detection apparatus of claim 2, wherein a thickness of the upper layer is relatively smaller than a thickness of the lower layer.

18. The detection apparatus of claim 2, wherein a coating including at least one of at least one hole-blocking material and at least one electron-blocking material is embodied between at least one of the upper layer and the upper electrode, between the upper layer and the middle electrode, between the lower layer and the middle electrode, and between the lower layer and the lower electrode.

19. The detection apparatus of claim 2, wherein at least one of the upper electrode and the lower electrode are structured and are coupled via a matrix circuit to the evaluation device, and wherein the evaluation device is embodied to detect at least one of interaction of the x-ray radiation with the first perovskite and interaction of x-ray radiation with the second perovskite in a spatially-resolved manner.

20. The detection apparatus of claim 2, wherein the evaluation device includes a plurality of evaluation units, and wherein at least one of the upper electrode and the lower electrode are structured and include a plurality of upper electrode elements or lower electrode elements, each respectively coupled to respective ones of a plurality of evaluation units.

21. The manufacturing method of claim 11, wherein the arrangement of the middle electrode between the upper layer and the lower layer comprises:
arranging a lower conductive layer on the lower layer;
arranging an upper conductive layer on the upper layer; and
connecting the lower conductive layer to the upper conductive layer via an intermediate conductive layer, the middle electrode including the lower conductive layer, the intermediate conductive layer and the upper conductive layer.

22. The manufacturing method of claim 11, wherein at least one of the upper layer and the lower layer are compressable by at least one of heating and exerting pressure.

23. The manufacturing method of claim 12, wherein at least one of the upper layer and the lower layer are compressable by at least one of heating and exerting pressure.
